(19) United States
(12) Patent Application Publication
(10) Pub. No.: US 2024/0266467 A1
(43) Pub. Date: Aug. 8, 2024

(54) LIGHT-EMITTING DIODE STRUCTURE

(71) Applicant: Taiwan-Asia Semiconductor Corporation, Hsinchu City (TW)

(72) Inventors: Kun-Te LIN, Hsinchu City (TW); Yueh-Lin LEE, Hsinchu City (TW); Ching-Yuan TSAI, Hsinchu City (TW)

(21) Appl. No.: 18/419,235

(22) Filed: Jan. 22, 2024

(30) Foreign Application Priority Data
Feb. 3, 2023 (TW) 112103936

(51) Int. Cl. H01L 33/22; H01L 33/12; H01L 33/38; H01L 33/62

(52) U.S. Cl. CPC H01L 33/22; H01L 33/12; H01L 33/382; H01L 33/62

(57) ABSTRACT

A light-emitting diode structure includes a substrate, a semiconductor light-emitting structure, and an electrode. The semiconductor light-emitting structure is located on the substrate, and the semiconductor light-emitting structure includes a top surface and a plurality of side walls. A surface roughening area is formed on the top surface. The electrode is located on the top surface. The surface roughening area is located between the electrode and the plurality of side walls, and the top surface forms a first flat part between the surface roughening area and the plurality of side walls.

### CROSS-REFERENCES TO RELATED APPLICATIONS

This application claims the benefit of priority to Taiwanese Patent Application No. 112103936 filed on Feb. 3, 2023, which is hereby incorporated by reference in its entirety.

### BACKGROUND OF THE INVENTION

### Field of the Invention

The present invention relates to a light-emitting diode structure, and in particular, to a light-emitting diode structure with both capability of resisting static discharge and the effect of improving luminous efficiency.

### Descriptions of the Related Art

In recent years, light-emitting diodes have been widely used in lighting, medical and 3C products. Light-emitting diode chips are mainly made of different semiconductor materials. By passing current through the connection surface of the two semiconductor materials, an electroluminescence effect is generated to convert electrical energy into light energy so that the light-emitting diode chip can not only emit higher brightness but also save more energy.

In the structural design of some light-emitting diode chips, a roughening process is performed on the surface of the light-emitting area, so as to achieve the effect of improving the luminous efficiency through the roughened surface. At present, most of the aforementioned roughening processes use a wet etching process. However, the wet etching process cannot control the shape of the surface roughening. Especially, irregular roughened surfaces will be formed near the edges of the wafer, which will cause the light-emitting diodes to the resistance of the chip itself to electrostatic discharge (ESD) is unstable, which increases the possibility that the light-emitting diode chip will be affected by electrostatic discharge.

Therefore, how to design a light-emitting diode structure that can improve the aforementioned problems is indeed a subject worthy of study.

### SUMMARY OF THE INVENTION

The object of the present invention is to provide a light-emitting diode structure that has both capability of resisting static discharge and the effect of improving luminous efficiency.

To achieve the above objective, the present invention provides a light-emitting diode structure, including a substrate, a semiconductor light-emitting structure, and an electrode. The semiconductor light-emitting structure is located on the substrate and includes a light-emitting surface and a plurality of side walls. A surface roughening area is formed on the light-emitting surface. The electrode is located on the light-emitting surface wherein the surface roughening area is located between the electrode and the plurality of side walls, and the light-emitting surface has a first flat part formed between the surface roughening area and the plurality of side walls.

In one embodiment of the present invention, the width of the first flat part is not less than 1 micrometer.

In one embodiment of the present invention, the surface roughening area is not higher than the first flat part.

In one embodiment of the present invention, the light-emitting surface has a second flat part formed between the surface roughening area and the electrode.

In one embodiment of the present invention, the surface roughening area is not higher than the second flat part.

In one embodiment of the present invention, the electrode includes a pad part and at least one extension part. One end of each of the extension part connects to the pad part, and the second flat part is located at the peripheral of the pad part and that of each of the extension part.

In one embodiment of the present invention, the light-emitting diode structure further comprises a transparent conductive layer, wherein the transparent conductive layer covers at least one part of the electrode, the second flat part and the surface roughening area.

In one embodiment of the present invention, the light-emitting diode structure further includes a transparent conductive layer, wherein the transparent conductive layer at least covers the surface roughening area.

In one embodiment of the present invention, the transparent conductive layer includes indium tin oxide, indium zinc oxide or indium gallium zinc oxide.

In one embodiment of the present invention, each of the plurality of side walls is a flat surface perpendicular to of the light-emitting surface.

In one embodiment of the present invention, the substrate is selected from a group consisted of silicon substrate, aluminum nitride substrate, sapphire substrate, copper tungsten substrate and molybdenum substrate.

In one embodiment of the present invention, the light-emitting diode structure further includes a buffer layer formed between the substrate and the semiconductor light-emitting structure, and the buffer layer is made of a material selected from a group consisted of silicon dioxide, aluminum oxide, gold, indium, tin, platinum, zinc, titanium, indium tin oxide, indium zinc oxide, indium gallium zinc oxide and zinc oxide.

Based on this, the light-emitting diode structure of the present invention utilizes the first flat part on the light-emitting surface, preventing the surface roughening area extending to the peripheral where the light-emitting surface contacts the side walls. This enhances the semiconductor light-emitting structure having the capability of resisting static discharge and the effect of maintaining luminous efficiency. Furthermore, the establishment of the first flat part also provides protection for each side wall of the semiconductor light-emitting structure, preventing etching processes from affecting the smoothness of each side wall. After reviewing the diagrams and subsequent descriptions, those skilled in the art will readily understand other objectives of the present invention, as well as the technical means and embodiments of the present invention.

### BRIEF DESCRIPTION OF THE DRAWINGS

FIG. 1 is a top view of the first embodiment of the light-emitting diode structure of the present invention.

FIG. 2 is a cross-sectional view of the first embodiment of the light-emitting diode structure of the present invention.

FIG. 3 is a cross-sectional view of the second embodiment of the light-emitting diode structure of the present invention.

### DETAILED DESCRIPTION OF THE PREFERRED EMBODIMENT

Due to the various embodiments and examples provided are illustrative and non-limiting, after reading this specification, those with ordinary skill in the art may recognize other embodiments and examples within the scope of the present invention. The features and advantages of such embodiments will be more apparent in light of the detailed description and the claims set forth below.

In this document, the terms “one” or “a” are used to describe the elements and components disclosed herein. This is done merely for convenience of explanation and provides a general sense to the scope of the present invention. Therefore, unless expressly indicated otherwise, such descriptions should be understood to encompass one or at least one, and the singular form also includes the plural.

In this document, terms such as “first” or “second” and similar ordinal numbers are primarily used to distinguish or refer to the same or similar elements or structures, and do not necessarily imply a spatial or temporal order of these elements or structures. It should be understood that, in certain situations or configurations, ordinal numbers can be interchanged without affecting the implementation of the present disclosure.

In this document, terms such as “comprising,” “having,” or any similar terms are intended to cover non-exclusively inclusive matter. For example, a component or structure comprising multiple elements is not limited solely to those elements explicitly listed herein but may include other elements that are typically inherent to such a component or structure.

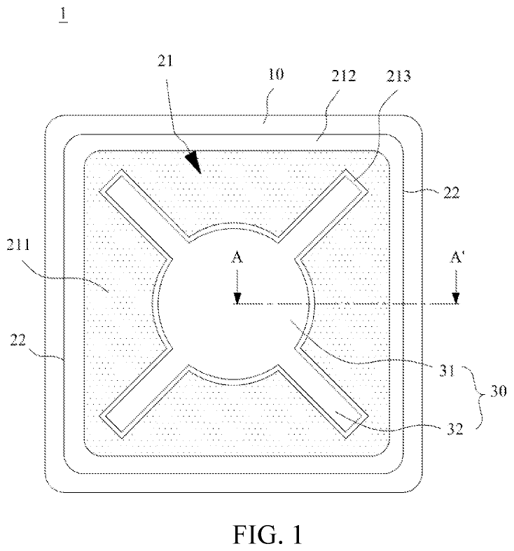

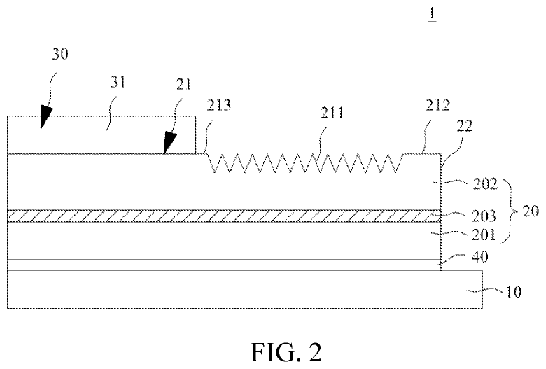

Please refer to FIG. 1 and FIG. 2 for the relevant diagrams of the first embodiment of the light-emitting diode structure of the present invention, where FIG. 2 is a cross-sectional view along line A-A′ of FIG. 1. As shown in FIG. 1 and FIG. 2, the light-emitting diode structure 1 of the present invention includes a substrate 10, a semiconductor light-emitting structure 20, and an electrode 30. The substrate 10 serves as the foundational component of the light-emitting diode structure 1 and can be silicon (Si) substrate, aluminum nitride (AlN) substrate, sapphire substrate, copper tungsten (CuW) substrate, or molybdenum (Mo) substrate, but not limited thereto.

The semiconductor light-emitting structure 20 is located on the substrate 10, and it is designed to generate electroluminescence and emit light. The semiconductor light-emitting structure 20 includes a light-emitting surface 21 and a plurality of side walls 22. The light-emitting surface 21 faces one side of the substrate 10, and the edge of the light-emitting surface 21 connects to the plurality of side walls 22. For example, the light-emitting surface 21 is approximately a rectangular surface, and each edge of the rectangular surface connects to one side wall 22. Each side wall 22 is a flat surface perpendicular to the light-emitting surface 21.

In one embodiment of the present invention, the semiconductor light-emitting structure 20 may further include a first semiconductor layer 201 and a second semiconductor layer 202. The first semiconductor layer 201 is adjacent to the substrate 10. In the following examples, gallium phosphide (GaP) is used as an example to illustrate the first semiconductor layer 201, but the present invention is not limited to this, and the first semiconductor layer 201 can also be made of other semiconductor materials. The first semiconductor layer 201 can be formed as an N-type semiconductor or P-type semiconductor by doping with different metals.

The second semiconductor layer 202 is located on the first semiconductor layer 201. In the following examples, aluminum gallium indium phosphide (AlGaInP) is used as an example to illustrate the second semiconductor layer 202, but the present invention is not limited to this, and the second semiconductor layer 202 can also be made of other semiconductor materials. The second semiconductor layer 202 can also be formed as an N-type semiconductor or P-type semiconductor by doping with different metals. Specifically, when the first semiconductor layer 201 is an N-type semiconductor, the second semiconductor layer 202 is a P-type semiconductor. Conversely, when the first semiconductor layer 201 is a P-type semiconductor, the second semiconductor layer 202 is an N-type semiconductor. A light-emitting layer 203 is formed between the first semiconductor layer 201 and the second semiconductor layer 202 (i.e., the junction surface between the first semiconductor layer 201 and the second semiconductor layer 202), and this light-emitting layer 203 is a multiple quantum well (MQW) layer.

Additionally, a buffer layer 40 may be further formed between the substrate 10 and the semiconductor light-emitting structure 20. The buffer layer 40 can handle the stress on the surface of the substrate 10, facilitating the formation of the semiconductor light-emitting structure 20 on the substrate 10. The buffer layer 40 can be made of materials such as silicon dioxide (SiO₂), aluminum oxide (Al₂O₃), gold (Au), indium (In), tin (Sn), platinum (Pt), zinc (Zn), titanium (Ti), indium tin oxide (ITO), indium zinc oxide (IZO), indium gallium zinc oxide (IGZO), or zinc oxide (ZnO).

The electrode 30 is located on the light-emitting surface 21 of the semiconductor light-emitting structure 20, and the electrode 30 can be connected to a power source. By applying power to the electrode 30, a current flows through the light-emitting layer 23, causing it to emit light. In the present invention, the electrode 30 includes at least a pad part 31 and at least one extension part 32. One end of each extension part 32 is connected to the pad part 31, and the other end of each extension part 32 extends in a direction away from the pad part 31. The pad part 31 can be used for soldering to circuitry connected to other electronic components, and each extension part 32 can serve as a power extension path to increase the luminous area and uniformity. However, the present invention is not limited to this configuration.

In the present invention, a surface roughening area 211 and a first flat part 212 is formed on the light-emitting surface 21 of the semiconductor light-emitting structure 20. The surface roughening area 211 is located between the electrode 30 and the plurality of side walls 22, and the first flat part 212 is located between the surface roughening area 211 and the plurality of side walls 22. In other words, the first flat part 212 spaces apart the surface roughening area 211 of the light-emitting surface 21 and the edge of the light-emitting surface 21. This arrangement prevents the surface roughening area 211 from extending to the edge of the light-emitting surface 21. The first flat part 212 can form a structure around the edge of the light-emitting surface 21.

The surface roughening area 211 is formed by using a wet etching process with chemical etchant. Due to the design of the first flat part 212, protective measures need to be performed during the wet etching process to reduce the possibility of the chemical etchant affecting the surface smoothness of the first flat part 212 and the plurality of side walls 22. From the external appearance of the structure, with or without the first flat part 212 on the light-emitting surface 21 can be used to determine whether the plurality of side walls 22 maintains surface smoothness.

In response to the aforementioned requirements, in the structural design of the present invention, the width of the first flat part 212 is not less than 1 micrometer (μm). After the wet etching process, the surface roughening area 211 is not higher than the first flat part 212. Irregular concave-convex structures can be formed on the surface roughening area 211.

Furthermore, in one embodiment of the present invention, a second flat part 213 is formed on the light-emitting surface 21 of the semiconductor light-emitting structure 20. The second flat part 213 is located between the surface roughening area 211 and the electrode 30. For example, the electrode 30 includes a pad part 31 and at least one extension part 32, and the second flat part 213 can be located at the peripheral of the pad part 31 and each extension part 32. In other words, the second flat part 213 can form a structure around the pad part 31 and each extension part 32. After the wet etching process, the surface roughening area 211 is not higher than the second flat part 213. The second flat part 213 ensures sufficient contact area between the electrode 30 and the light-emitting surface 21 of the semiconductor light-emitting structure 20 to facilitate the formation of ohmic contact between them.

Therefore, the light-emitting diode structure 1 of the present invention, by having the first flat part 212 with a sufficient width, avoids the extension of the surface roughening area 211 of the light-emitting surface 21 to the edge of the light-emitting surface 21. This eliminates the instability factor of the semiconductor light-emitting structure 20 in resisting electrostatic discharge, and enhances the ability to resist electrostatic discharge. Meanwhile, the surface roughening area 211 can improve the overall luminous efficiency.

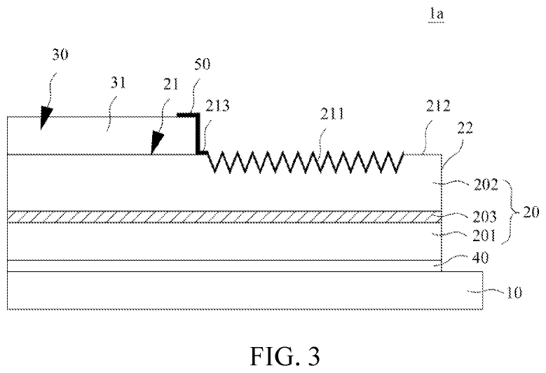

Please refer to the sectional view of the second embodiment of the light-emitting diode structure of the present invention in FIG. 3. This embodiment is a modified form of the previous first embodiment. As shown in FIG. 3, in this embodiment, the light-emitting diode structure 1a of the present invention further includes a transparent conductive layer 50. The transparent conductive layer 50 at least covers the surface roughening area 211 of the light-emitting surface 21 of the semiconductor light-emitting structure 20. In one embodiment of the present invention, the transparent conductive layer 50 may cover at least a portion of the electrode 30 (such as a localized surface of the aforementioned pad part and the overall surface of each extension part), the second flat part 213 of the light-emitting surface 21, and the surface roughening area 211. The transparent conductive layer 50 is selected from a group consisted of indium tin oxide (ITO), indium zinc oxide (IZO), and indium gallium zinc oxide (IGZO). By placing the transparent conductive layer 50, after supplying power to the electrode 30, the current can diffuse not only to the electrode 30 itself but also to the transparent conductive layer 50 to further enhance the luminous efficiency and electrostatic discharge resistance. The transparent conductive layer 50 does not cover the first flat part 212 to ensure that the transparent conductive layer 50 does not indirectly or directly contact each of the side walls 22 of the semiconductor light-emitting structure 20.

The above embodiments are provided for illustrative purposes and to explain the technical features of the present invention, and are not intended to limit the scope of protection of the present invention. Any modifications or equivalents that can be easily made by those skilled in the art are within the scope claimed by the present invention, and the scope of protection of the present invention shall be determined by the scope of the patent application.

1. A light-emitting diode structure, including:
a substrate,
a semiconductor light-emitting structure located on the substrate, and the semiconductor light-emitting structure including a light-emitting surface and a plurality of side walls, and the light-emitting surface having a surface roughening area; and
an electrode located on the light-emitting surface,
wherein the surface roughening area is located between the electrode and the plurality of side walls, and the light-emitting surface has a first flat part formed between the surface roughening area and the plurality of side walls.

2. The light-emitting diode structure of claim 1, wherein a width of the first flat part is not less than 1 micrometer.

3. The light-emitting diode structure of claim 1, wherein the surface roughening area is not higher than the first flat part.

4. The light-emitting diode structure of claim 1, wherein the light-emitting surface has a second flat part formed between the surface roughening area and the electrode.

5. The light-emitting diode structure of claim 4, wherein the surface roughening area is not higher than the second flat part.

6. The light-emitting diode structure of claim 4, wherein the electrode includes a pad part and at least one extension part, one end of each of the extension part connects to the pad part, and the second flat part is located at a peripheral of the pad part and that of each of the extension part.

7. The light-emitting diode structure of claim 4, further including a transparent conductive layer, wherein the transparent conductive layer covers the at least one part of the electrode, the second flat part and the surface roughening area.

8. The light-emitting diode structure of claim 1, further including a transparent conductive layer, wherein the transparent conductive layer at least covers the surface roughening area.

9. The light-emitting diode structure of claim 7, wherein the transparent conductive layer includes indium tin oxide, indium zinc oxide or indium gallium zinc oxide.

10. The light-emitting diode structure of claim 1, wherein each of the plurality of side walls is perpendicular to a flat surface of the light-emitting surface.

11. The light-emitting diode structure of claim 1, wherein the substrate is selected from a group consisted of silicon substrate, aluminum nitride substrate, sapphire substrate, copper tungsten substrate and molybdenum substrate.

12. The light-emitting diode structure of claim 1, further including a buffer layer formed between the substrate and the semiconductor light-emitting structure, and the buffer layer is made of a material selected from a group consisted of silicon dioxide, aluminum oxide, gold, indium, tin, platinum, zinc, titanium, indium tin oxide, indium zinc oxide, indium oxide Made of gallium zinc and zinc oxide.
